(19) United States
(12) Patent Application Publication
(10) Pub. No.: US 2024/0193337 A1
(43) Pub. Date: Jun. 13, 2024

(54) TRACKING COVERAGE ARTIFACTS FOR PERIODIC SIGNALS USING SEQUENCE-BASED ABSTRACTIONS

(71) Applicant: Indian Institute of Technology Kharagpur, Kharagpur (IN)

(72) Inventors: Ayan Chakraborty, Kolkata (IN); Sayandeep Sanyal, Kharagpur (IN); Pallab Dasgupta, Kharagpur (IN); Aritra Hazra, Kharagpur (IN); Scott Morrison, Dallas, TX (US); Sudhakar Surendran, Bangalore (IN); Lakshmanan Balasubramanian, Bangalore (IN); Mohammad Moshiur Rahman, Allen, TX (US)

(21) Appl. No.: 18/076,547

(22) Filed: Dec. 7, 2022

(51) Int. Cl. G06F 30/367; G06F 30/373

(52) U.S. Cl. CPC G06F 30/367; G06F 30/373

(57) ABSTRACT

The present disclosure provides for encoding the signal using a window-based partitioned sequence of literals and then operating over this sequence to determine relevant periodic artifacts. A signal can be received, and then the signal can be abstracted to a sequence of literals. Repeating sub-sequences of literals can be identified in windows of time that increase in width until a repeating sub-sequence is found. Once a repeating sub-sequence is found, the window of time is shifted, and the process repeated. Once the temporal variations of the artifacts are known for the signal, the reference voltage at each of the time periods can be found by resampling the signal in different windows of time, finding temporary reference voltages that are means of samples in each window, determining the reference voltages for each time period, and then determining the DC reference based on a median of the list of reference values.

### FIELD OF THE DISCLOSURE

The present disclosure relates to tracking artifacts of a periodic signal, and more specifically to tracking artifacts of the periodic signal without prior information about the signal.

### BACKGROUND

Verification of Analog and Mixed Signal (AMS) designs has become a major challenge for the VLSI industry, owing to the increasing use of analog components in safety-critical application domains, such as automotive, avionics, and health monitoring devices. Industrial safety standards demand zero Defects Parts Per Million (DPPM) on the delivered products and thereby the onus is on verification and test engineers to achieve very high functional, parametric and structural coverage through a suitably laid out verification and test plan respectively.

Periodic signals are very common in AMS systems, and often there is an interest in tracking periodic events, that is events that occur following some recurrent patterns. Changes in periodicity may indicate anomalous behavior, such as jitter in the output of a Phase Locked Loop (PLL), change in frequency of ripples in a buck converter, or frequency drops in power grids. These and other anomalies may be the outcome of various unavoidable factors like parametric deviations in transistors, parasitic capacitances, field conditions like temperature, load on the circuit, presence of manufacturing defects etc. The distortion may come in various forms, such as a sudden drop in frequency due to the loading of the circuit, or a shift in the reference level about which the signal is oscillating. While some repercussions are of less concern to a designer, others, especially the ones dealing with communication devices, are often critical. Hence, it becomes imperative to include such functional artifacts in the coverage specifications of AMS designs.

Contrary to the verification and coverage procedures followed for safety-critical signals in a design, the treatment of periodic signals is different because most periodic anomalies are not instantaneous and cannot be detected immediately. Consequently, a computer aided design (CAD) framework for automatically tracking periodic artifacts alleviates the verification and test engineer from visually looking for anomalies. Automating the maintenance of coverage information related to periodic artifacts is equally important. As an example, the graph 102 in FIG. 1 shows a scenario where a signal is pulsating at a high frequency (100 Hz) during time frame 104 about reference 1.2V. Due to thermal throttling at 0.2 s, the frequency had to be decreased to 50 Hz for time frame 106, while the reference was also lowered to 0.7V. The designer would wish to track the changes in both frequency and the reference level. A computation of frequency by any standard tool, requires the user to provide a single reference value about which the frequency of the entire signal is computed. However, there does not exist a common reference voltage level about which both the frequencies during time frames 104 and 106 can be measured.

Computing the frequency of a periodic signal is relatively straight forward from a CAD perspective, when the reference voltage about which it is pulsating is known beforehand. This can be done during simulation using AMS verification and coverage frameworks (such as CoveRT [6]). On the other hand, when the reference voltage is not known, or it is known that the reference voltage changes from time to time, then the algorithmic challenge becomes more significant. From a designer's perspective, it is impossible to accurately specify the value(s) of reference(s) beforehand due to the inherent unpredictability of the circuit operating conditions or the complexity of manually specifying all possible intended outcomes under all possible circuit operating conditions as mentioned earlier.

The problem of tracking frequency across time without any prior knowledge of Direct Current (DC) reference level is a longstanding problem with applications in many fields ranging from early warning systems for earthquakes to fault diagnosis in industrial systems. Initial approaches focused on modifying classical Fourier transform, leading to the development of methods like the Short Time Fourier Transform (STFT), and distributions such as the Wigner Ville Distribution to represent a joint distribution in time and frequency. However, both of these methods have their drawbacks. The STFT is heavily dependent on parameters such as window length, and the type of window used. Hence, an approximate knowledge of the duration of a frequency segment must be known beforehand for effective application. The STFT's time-frequency resolution is also inherently limited by Heisenberg's Uncertainty Principle. Although the Wigner Ville Distribution provides superior time-frequency resolution, it suffers from the drawback of cross-term interfaces present at the centers of each pair of actual frequency components. Wavelet Transform and its modern variant Synchrosqueezed Wavelet Transforms represents another class of approaches that aims to represent a signal as a superposition of wavelets of different periodicity. They are superior to STFT, in the sense that their low-frequency resolution is much better, but still, their high-frequency resolution is limited by Heisenberg's Uncertainty Principle. Modern approaches like the GaborWigner Transform have tried to combine the best of two methods, with limited success. Adaptive LMS Algorithms is a machine learning based algorithm which give very precise results, but its application is limited to sinusoidal signals. It also suffers for being heavily dependent on the hyperparameters. There have been domain-specific methods as well such as the Local Mean Decomposition Method for EEG.

### SUMMARY

Methods and systems disclosed herein provide for tracking coverage artifacts for periodic signals using sequence-based abstractions. The present disclosure proposes a novel methodology to compute various artifacts of a periodic signal algorithmically in absence of prior information regarding the periodic nature of the signal. The present disclosure provides for encoding the signal using a window-based partitioned sequence of literals and then operating over this sequence to glean out the relevant periodic artifacts. A signal can be received, and then the signal can be abstracted to a sequence of literals. Repeating sub-sequences of literals can be identified in windows of time that gradually increase until a repeating sub-sequence is found. Once a repeating sub-sequence is found the window of time can be shifted, and the process repeated. Once the temporal variations of the artifacts are known for the signal at different time periods, the reference voltage at each of the time periods can be found by uniformly resampling the signal, or performing a weighted average of a non-uniformly sampled signal in different windows of time, finding temporary reference voltages that are means of all samples in each window of time, determining the reference voltages for each time period, and then determining a DC reference based on a median of the list of reference values.

In an embodiment, a method to determine parameters of a periodic coverage artifact in a signal can include sampling the signal to abstract it as an ordered set of a sequence of literals that correspond to a sequence of time stamps in a first time period. The method can also include iteratively determining whether a sub-sequence of literals repeats in a first window of time within the first time period, wherein after every iteration, the first window of time is lengthened. The method can also include determining a frequency of the periodic coverage artifact based on a length of time between repeating sub-sequences of literals. The method can also include uniformly resampling the signal in a second window of time to determine a temporary reference voltage that is a mean of all samples in the second window of time. In an embodiment, the second window of time comprises at least two occurrences of the repeating sub-sequences of literals. The method can also include determining a list of reference values for a set of time periods, wherein a reference value of the list of reference values is a mean of each sample in a respective time period, wherein each time period of the set of time periods is defined by consecutive positive (or negative) level crossings of the temporary reference voltage. The method can also include determining a DC reference based on a median of the list of reference values.

In another embodiment, a signal processing device can include a memory that stores computer-executable instructions. The signal processing device can also include a processor that executes the computer-executable instructions to perform operations. The operations can include sampling the signal to abstract it as an ordered set of a sequence of literals that correspond to a time stamps in a first time period. The operations can also include iteratively determining whether a sub-sequence of literals repeats in a first window of time within the first time period, wherein after every iteration, the first window of time is lengthened. The operations can also include determining a frequency of the periodic coverage artifact based on a length of time between repeating sub-sequences of literals. The operations can also include uniformly resampling the signal in a second window of time to determine a temporary reference voltage that is a mean of all samples in the second window of time. The operations can also include determining a list of reference values for a set of time periods, wherein a reference value of the list of reference values is a mean of each sample in a respective time period, wherein each time period of the set of time periods is defined by consecutive positive (or negative) level crossings of the temporary reference voltage. The operations can also include determining a DC reference based on a median of the list of reference values.

In another embodiment, a non-transitory computer-readable medium comprising computer executable instructions, that when executed by a processor, perform operations. The operations can include sampling the signal to abstract it as an ordered set of a sequence of literals that correspond to a time stamps in a first time period. The operations can also include iteratively determining whether a sub-sequence of literals repeats in a first window of time within the first time period, wherein after every iteration, the first window of time is lengthened. The operations can also include determining a frequency of the periodic coverage artifact based on a length of time between repeating sub-sequences of literals. The operations can also include uniformly resampling the signal in a second window of time to determine a temporary reference voltage that is a mean of all samples in the second window of time. The operations can also include determining a list of reference values for a set of time periods, wherein a reference value of the list of reference values is a mean of each sample in a respective time period, wherein each time period of the set of time periods is defined by consecutive positive (or negative) level crossings of the temporary reference voltage. The operations can also include determining a DC reference based on a median of the list of reference values.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 depicts a graph showing a signal with varying frequency and reference level according to one or more embodiments of the present disclosure.

FIG. 2 depicts a graph showing periodic signal with sequence based abstraction according to one or more embodiments of the present disclosure.

FIG. 3 depicts an algorithm for window-based tracking according to one or more embodiments of the present disclosure.

FIGS. 4A-4F depict various graphs showing experimental results on waveforms according to one or more embodiments of the present disclosure.

FIG. 5 depicts a graph showing a zoomed in portion of a graph from FIG. 4A according to one or more embodiments of the present disclosure.

FIG. 6 depicts a signal processing device according to one or more embodiments of the present disclosure.

FIG. 7 is a flowchart of a method to determine parameters of a periodic coverage artifact in a signal according to one or more embodiments of the present disclosure.

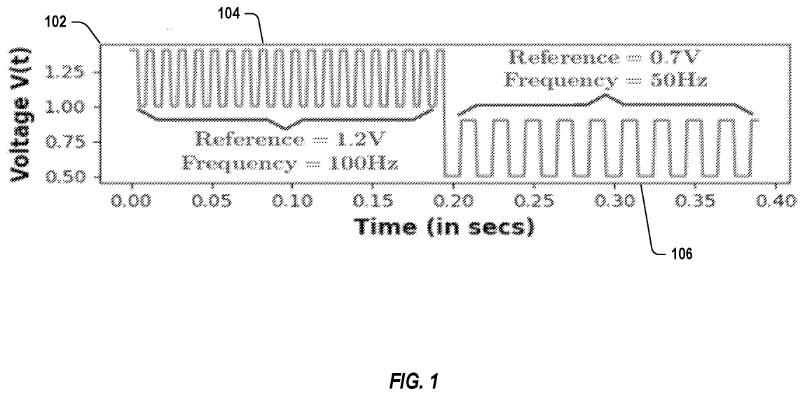

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

Periodic signals and recurrent events are very common in Analog and Mixed-Signal (AMS) behaviors. Tracking attributes related to frequency and recurrent behaviors is an integral part of the verification coverage plan for AMS designs. It is straight-forward to validate periodic artifacts in a signal, such as frequency or duty cycle, when a reference value is provided. From a computer aided design (CAD) perspective, the difficulty arises when a reference is not provided, and more so when a static reference does not exist. The present disclosure proposes a novel methodology to compute various artifacts of a periodic signal algorithmically in absence of prior information regarding the periodic nature of the signal. The present disclosure provides for encoding the signal using a window-based partitioned sequence of literals and then operating over this sequence to glean out the relevant periodic artifacts. Experiments performed on waveforms collected from industrial test cases and medical benchmarks demonstrate the efficacy of the proposed methodology.

In the disclosed approach the signal is abstracted out as a sequence of events to carry out further computations. This abstraction also enables the ability to compute periodic artifacts for events occurring at periodic intervals. It is to be noted that the primary intention is not to find the fundamental frequency of the entire signal, which can be done using a standard frequency domain transform. It is desirable to track how frequency of the signal varies with time, and also handle scenarios where frequency≈0. The primary contributions of this work are summarized below:

Proposed are different coverage artifacts for periodic signals and also a language for specifying these artifacts.

Proposed is a sequence-based abstraction of a signal for computing different periodic artifacts.

Proposed are novel algorithms to compute frequency, Direct Current (DC) reference level, peak-to-peak amplitude, and duty cycle of a periodic signal with no prior information.

The efficacy of the proposed methods over waveforms generated from industrial benchmark circuits and electrocardiogram (ECG) waveforms is shown.

The time-series representation of a periodic signal and the various artifacts of a periodic signal is defined in the following:

Definition 1. [Time-series of a signal]: Time-series of a signal x is a mapping τₓ: T→X, where T={t₁, t₂, . . . , tₙ}, (tᵢ∈ [symbol] _{≥0}, ∀i∈[1, n]) and X∈ [symbol] . The value of x at a time point t∈T in the time-series τₓ is given as τₓ(t).

val (τₓ)={τₓ(t₁), τₓ(t₂), . . . , τₓ(tₙ)} is used to denote the set of value points. Then time (τₓ)={t₁, . . . , tₙ} is used to denote the time points in the time-series τₓ. Then t₁=min(time (τₓ)) and tₙ=max(time (τₓ)) respectively denote the first and last time points in time (τₓ). n=len (τₓ) is used to denote the number of data points present in τₓ.τₓ^{[t}^{ᵢ}^{:t}^{_{j]}} which denotes the part of the timeseries within time interval [tᵢ:tⱼ].

Definition 2. [Periodic signal]: Given a time-series τₓ if ∃i,j,k,l,tₖ<tᵢ&tₗ>tⱼ such that τₓ^{[t}^{ᵢ}^{:t}^{ⱼ}^{]}, repeats itself over the time period [tₖ: t₁], then the signal is said to be periodic over the time interval [tₖ:tₗ].

The sub-sequence τₓ^{[t}^{ᵢ}^{:t}^{ⱼ}^{]} is then referred to as a single cycle. The time period is the duration of time of one cycle in a repeating event, hence given as T=tⱼ−tᵢ. Note that, the periodic signals are closed over concatenation operator. Therefore, multiple distinct periods can be found for the resultant signal.

Coverage Artifact 1. [Frequency]: Given a periodic timeseries τₓ with τₓ^{[t}^{ᵢ}^{:t}^{ⱼ}^{]} representing one cycle, the frequency of the time-series for the duration in which τₓ^{[t}^{ᵢ}^{:t}^{ⱼ}^{]} repeats itself is given as F=1/(tⱼ−tᵢ).

Coverage Artifact 2. [DC Reference]: Given a periodic timeseries τₓ with τₓ^{[t}^{ᵢ}^{:t}^{ⱼ}^{]} representing one cycle, the DC Reference of the time-series for the duration in which τₓ^{[t}^{ᵢ}^{:t}^{ⱼ}^{]} repeats itself is given by DC=mean (τ′ₓ^{[t}^{ᵢ}^{:t}^{ⱼ}^{]}), where τ′ₓ is the uniformly sampled version of time-series τₓ.

Coverage Artifact 3. [Peak-to-Peak Amplitude]: Given a periodic time-series τₓ with τₓ^{[t}^{ᵢ}^{:t}^{ⱼ}^{]} representing one cycle, the Peak to Peak Amplitude of the time-series for the duration in which τₓ^{[t}^{ᵢ}^{:t}^{ⱼ}^{]} repeats itself is defined as the difference of the maximum and minimum values of the time-series, and it is given as P=max (τₓ^{[t}^{ᵢ}^{:t}^{ⱼ}^{]})−min (τₓ^{[t}^{ᵢ}^{:t}^{ⱼ}^{]}).

Coverage Artifact 4. [Duty Cycle]: Given a periodic timeseries τₓ, and a threshold value p∈ [symbol] , with τₓ^{[t}^{ᵢ}^{:t}^{ⱼ}^{]} representing one cycle, Duty Cycle is defined as the fraction of the time period, the series assumes a value greater than p. It is calculated as follows,

$$\frac{{t}_{n} - {t}_{m}}{{t}_{j} - {t}_{i}} \vert ( {τ}_{x}^{[ {t}_{m} : {t}_{n} ]} ⊂ {τ}_{x}^{[ {t}_{i} : {t}_{j} ]} ) \& ( {τ}_{x}^{[ {t}_{m} : {t}_{n} ]} ( t ) > p ∀ {t}_{m} \leq t \leq {t}_{n} ) \& ( {τ}_{x}^{[ {t}_{i} : {t}_{m} ]} ( t ) \leq p ∀ {t}_{i} \leq t \leq {t}_{m} ) \& ( {τ}_{x}^{[ {t}_{n} : {t}_{j} ]} ( t ) \leq p ∀ {t}_{n} \leq t \leq {t}_{j} )$$

Unless provided, the DC Reference value identified for τₓ^{[t}^{ᵢ}^{:t}^{ₘ}^{]} is taken as default value of p.

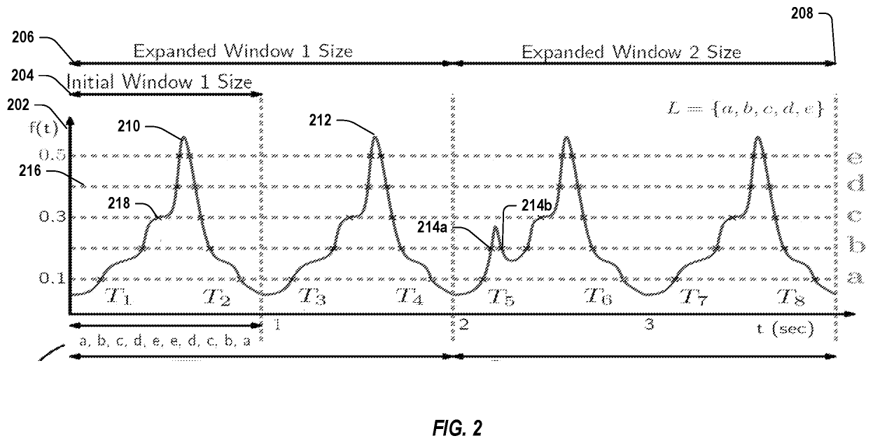

For the waveform shown in graph 202 of FIG. 2, the values of frequency may be given as

$$\frac{1}{{T}_{3} - {T}_{1}} , \frac{1}{{T}_{4} - {T}_{2}} , \frac{1}{{T}_{7} - {T}_{3}} ,$$

and so on. Whereas, the values of DC reference and peak-to-peak amplitude can be identified as 0.3 and 0.5 respectively. Given any one of these artifacts, the computation of the other three artifacts becomes a trivial job. The crux of the problem formulation lies in this very statement and proposed are algorithms to compute all four artifacts in absence of such information.

The primary target for the application of the proposed artifact tracking methodology is the semiconductor industry. SystemVerilog is a widely used language for specifying coverage in the digital domain and the verification engineers are well-versed in it. Hence the proposed language has been kept close to SystemVerilog for easy adaptation. The following shows the generic syntax of the proposed language.
<instantiation_name>::<coverage_artefact>#( );
<coverpoint_name>:coverpoint <instantation_name>(<signal>) [iff (condition)][{targets}];
   Portions given in square braces denote optional arguments. Example 1. A frequency and DC reference coverage artifacts on the signal 218 in FIG. 2 can be specified as follows:
freq_1::frequency #( );
dc_1::dc_reference #( );
ft_freq:coverpoint freq_1(f(t));
ft_dc:coverpoint dc_1(f(t));

Example 2. The following specifies a frequency coverage artifact on the signal V(vout).

```
freq_1 :: frequency#( );
vout_freq : coverpoint freq_1(V(vout)) iff (en==1){
  bins low_freq = [1.2e6: 1.5e6];
  bins high_freq = [2e6: 2.3e6];
  illegal_bins not_allowed = [1.7e6: 1.9e6];};
```

freq_1 is an instantiation name of the frequency coverage artifact, while vout_freq is the name for the coverpoint. The condition and target specifications attached to it enhances the expressiveness of the language. It states that the coverpoint vout_freq will be activated, that is, the frequency of V(vout) will be computed only when en is high. The target criterion specifies that the bins low_freq and high_freq is to be covered, and it should be flagged if the frequency of V(vout) goes into the range of 1.7 MHz to 1.9 MHz referred to as illegal bins.

The computed periodic coverage artifacts are dumped in a time-series format. This gives the ability to apply the coverage artifacts recursively. For example, the following declaration computes the frequency at which the frequency of V(vout) changes.
vout_freq_freq:coverpoint freq_1(vout__freq);

Similar provisions are also applicable to other periodic coverage artifacts defined in previous section.

The problem of tracking frequency is therefore reformulated as a pattern matching problem. The general idea is that a discrete value approximation of a periodic signal will have an inherent repeating pattern associated with it. The algorithm is described with the example of a periodic waveform given in FIG. 2.

1. Abstracting Signal as a Sequence of Literals: The value domain of the time-series is discretized into r equidistant values {x₁, x₂, . . . , xᵣ}. A set of literals L={s₁, s₂ . . . , sᵣ} is created such that ∀i∈[1:r]xᵢ is labelled with sᵢ. For a given time-series τ_{f} and set of literals L (e.g., 218) two ordered sets are constructed, namely, a sequence literals [symbol] _{τ}_{_{f}}^{L}, and a sequence of time-stamps [symbol] _{τ}_{_{f}}^{L}. Following are the rules of abstraction.

If τ_{f} crosses xᵢ at time ∃i,j,k,l,tₖ<tᵢ&tₗ>tⱼ, and [symbol] _{τ}_{_{f}}^{L}+ [symbol] _{τ}_{_{f}}^{L}+{tⱼ}

∀{Sᵢ,Sᵢ₊₁}∈ [symbol] _{τ}_{_{f}}^{L}∧{tᵢ,tᵢ₊₁}∈ [symbol] _{τ}_{_{f}}^{L}⇒tᵢ<tᵢ₊₁,d

The value of r controls the amount of information that is retained after abstraction. Higher its value, higher is information retention, hence better accuracy in subsequent computations. The following theorem is utilized to extract the sub-sequence of [symbol] _{τ}_{_{f}}^{L} which corresponds to a single period of signal f(t).

Theorem 1. For a periodic continuous signal f(t), a period of f(t) will be denoted by the sequence s_{τ}_{_{f}}^{L} such that s_{τ}_{_{f}}^{L} is the shortest repeating sub-sequence of [symbol] _{τ}_{_{f}}^{L}, that is s_{τ}_{_{f}}^{L}=argmin (|s′|) given [symbol] _{τ}_{_{f}}^{L}=s′*.

Proof (by contradiction). Suppose, s_{τ}_{_{f}}^{L} is the sub-sequence denoting one period in f(t). Also, there exists a sub-sequence s′ such that |s′|<s_{τ}_{_{f}}^{L}| and [symbol] _{τ}_{_{f}}^{L}=s′*. Since f(t) is continuous and periodic, the order in which it crosses each of the discrete values will remain unchanged. According to an assumption, concatenation of sub-sequence s′ will result in [symbol] _{τ}_{_{f}}^{L}, indicating that concatenation of the portion of f(t) corresponding to s′ will give back f(t). This makes s′ to be the sub-sequence corresponding to a period in f(t), contradicting the assumption. So, s_{τ}_{_{f}}^{L} must be the shortest sub-sequence of [symbol] _{τ}_{_{f}}^{L}.

Example 3. For the waveform given in FIG. 2 the value domain is discretized with values 216 placed 0.1 apart (0.1. 0.2, 0.3, 0.4, 0.5, etc.), and is labelled with literals L={a, b, c, d, e}. The extracted sequence is, [symbol] _{τ}_{_{f}}^{L}={a, b, c, d, e, e, d, c, b, a, a, b, c, d, e, e, d, c, b, a, . . . }. A period of the waveform can be expressed by the shortest repeating subsequence s_{τ}_{_{f}}^{L}={a, b, c, d, e, e, d, c, b, a}. (e.g., the sequence of literals between peak 210 and 212.

2. Finding Smallest Repeating Sub-sequence: A direct application of an exhaustive search algorithm may not be fruitful owing to the possible presence of noise in the signal. Noise in a signal may introduce spurious crossings which can corrupt the original sequence. Further measures can be deployed in various embodiments to overcome this challenge. These are listed as follows.

a) Sequence Matching with Tolerance: A tolerance parameter τ is introduced which is defined as the maximum number of literals that are allowed to be neglected in the computation of the shortest repeating sub-sequence. The signal in FIG. 2 shows two spurious crossings of b at 214a and 214b due to a glitch in its third cycle. These spurious crossings should be neglected while searching for the shortest repeating sub-sequence. The search problem reduces to an approximate sequence matching problem.

b) Leveraging Continuity of Signals: Two observations are made use of for continuous signals to prune down the search space for the correct sub-sequence. Firstly, the number of crossings in a single cycle will always be an even number. Secondly, for any literal in a valid sequence, its preceding and succeeding literals have to be one of its immediate neighbors. For example, for the abstraction in FIG. 2, the preceding and succeeding literals of c can only take values from {b, c, d} only. Hence, a sequence like {a, b, c, e, d} is an invalid sequence. This leads to the fact that the subsequence representing one fundamental period has to be a palindrome, in order for the sequence to repeat itself.

Along with the smallest repeating sub-sequence s_{τ}_{_{f}}^{L}, generated are two lists T_{S} and T_{E} to store the starting and ending time stamps respectively for all occurrences of s_{τ}_{_{f}}^{L} in [symbol] _{τ}_{_{f}}^{L}. Time period TP may be computed as follows:

tp_{S}={tᵢ₊₁−tᵢ|tᵢ,tᵢ₊₁∈T_{S}},tp_{E}{tᵢ₊₁−tᵢ|tᵢ,tᵢ₊₁∈T_{E}}

TP=median(tᵢ)∀tᵢ∈{tp_{S}}+{tp_{E}}

Frequency is the inverse of TP.

3. Application to Signals with Varying Frequency: A window-wise computation of frequency is followed for realworld signals whose frequency often varies with time. The general idea is to look into a part of the given time-series and figure out if a periodicity resides in the window. The window length w is gradually increased (e.g., the method starts with window 204, then increased to window 206) till a period is found. Once the frequency of periodicity within a window has been computed, the window is shifted right on the time axis (e.g., window 208) and the computation continues in a similar manner until the entire time-series is exhausted.

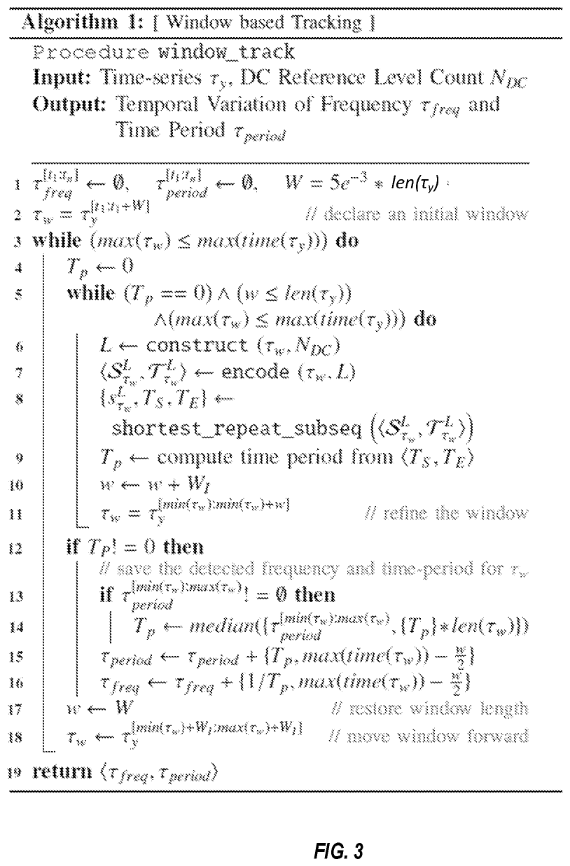

Algorithm 1 in FIG. 3 explains the procedure in detail. Initial window length W is taken as 0.5% of len (τ_{y}), window increment length Wₗ is taken as 10% of W. It internally uses three sub-routines as detailed below.
construct (τₓ,N_{DC}): constructs the set of literals for window τₓ using N_{DC} number of literals as described above.
encode (τₓ,L): returns the ordered set of literals [symbol] _{τ}_{ₓ}^{L} and time-stamps of crossing [symbol] _{τ}_{ₓ}^{L} in parlance of the abstraction as described above.
shortest_repeat_subseq ( [symbol] _{τ}_{_{w}}^{L} [symbol] _{τ}_{_{w}}^{L} [symbol] ): returns the smallest repeating sub-sequence, s_{τ}_{_{f}}^{L}, along with starting (T_{S}) and ending (T_{E}) time-stamps for all occurrences of s_{τ}_{_{f}}^{L}, as explained above.

Example 4. In FIG. 2, the initial window ranges from [0:1]s and [symbol] _{τ}_{_{f}}^{L}={a, b, c, d, e, e, d, c, b, a} is the corresponding sequence. In this sequence, there is no repeating sub-sequence. Hence the window is expanded to window 206 until a repeating sub-sequence is found for the resulting window. In this case, such a window is from [0: 2]s where portions τ_{f}^{[T}^{₁}^{:T}^{₃}^{]} and τ_{f}^{[T}^{₂}^{:T}^{₄}^{]} have been identified as two periods. The frequency for this window is assigned as:

τ_{freq}^{[T}^{₁}^{:T}^{₄}^{]}=1/median{(T₃−T₁),(T₄−T₂)}

A notable point is that while producing time-series from a continuous real-valued signal, the signal values may not be uniformly sampled. Hence the exact positions of crossing for a particular DC Level may not be known. In such a scenario piece-wise-linearity is assumed to get the exact timestamp of the crossing. This enables the ability to work with adaptively sampled signals, without needing to re-sample uniformly.

Once the knowledge of temporal variations of frequency is known, tracking values of other parameters becomes relatively straightforward. A window [symbol] of some initial length is taken as the starting window, and the window is increased in window length until the time duration of the window is just greater than at least two times the value of the time period calculated for [symbol] . Windows with larger sizes will not capture the time variation of DC reference accurately while smaller-sized windows will be too noisy. This also ensures that there are at least two cycles of the periodic signal inside the window. However, the reference value cannot be directly computed as the mean of all samples inside this window for two reasons. Firstly, the signal may be adaptively sampled. Secondly, there may be some points inside the window which are not part of any cycle, and hence, can skew the mean. The window is first re-sampled uniformly and a temporary DC reference rₜₑₘₚ is calculated as the mean of all samples. Any two consecutive positive (or negative) level crossings of rₜₑₘₚ represents one period. A list of reference values R={r₁, . . . , rₚ} are computed as the mean of all samples for each period. The actual DC reference is taken as the median of R.

The peak-to-peak value of a period is computed as the difference between the maximum and minimum value points in the period. For a given window [symbol] the peak-to-peak value [symbol] is taken as the median of peak to peak values of all the periods present [symbol] . The median in all the calculations is taken to mitigate the effects of outliers. Outliers are edge cases for example when a signal suddenly changes its behavior. For example, if the peak to peak voltage suddenly drops, we may get one outlier corresponding to the first period in which the peak to peak voltage was high. This skews the measurements although the rest of the periods show steady peak to peak voltage.

The knowledge of temporal variations of frequency and DC level is utilized to compute the duty cycle variations. The size of the window is taken such that it contains at least two cycles as the periodic signal for the same reason as discussed earlier. The actual DC level of that window is used to calculate the positions of level crossings. The time interval between a positive (or negative) level crossing and the next negative (or positive) level crossing gives us the on-time Tₒₙ of the signal. Hence, duty cycle is simply calculated as

$$\frac{{T}_{on}}{{T}_{period}}$$

where T_{period} is the time period computed for the window under consideration. In case, there are multiple periods inside the window, the median of all detected duty cycle values is taken. As the signal may be adaptively sampled, the exact time step of the level crossing may not be known. So, piece-wise linearity is assumed to calculate the exact time step.

The methodology has been applied on different waveforms, including a set of industrial circuits, an AMS benchmark circuit, and a set of ECG signals from an open dataset. The temporal variations of frequency, DC reference, peak-to-peak amplitude, and duty cycle (if applicable) are computed.

All experiments were done on a laptop having Intel Core™ i5-8250U CPU @ 1.60 GHz with 8 GB of DDR4

| Waveform | # of samples | Execution time | |
|---|---|---|---|
| Oscillator output | 54100 | 4.33 | s |
| Buck Regulator output | 331988 | 210.43 | s |
| PLL output | 125263 | 5.39 | s |
| Audio amplifier (Bug scenario 1) | 10000 | 8.58 | s |
| Audio amplifier (Bug scenario 2) | 10000 | 8.39 | s |
| ECG Waveform | 3600 | 0.25 | s |

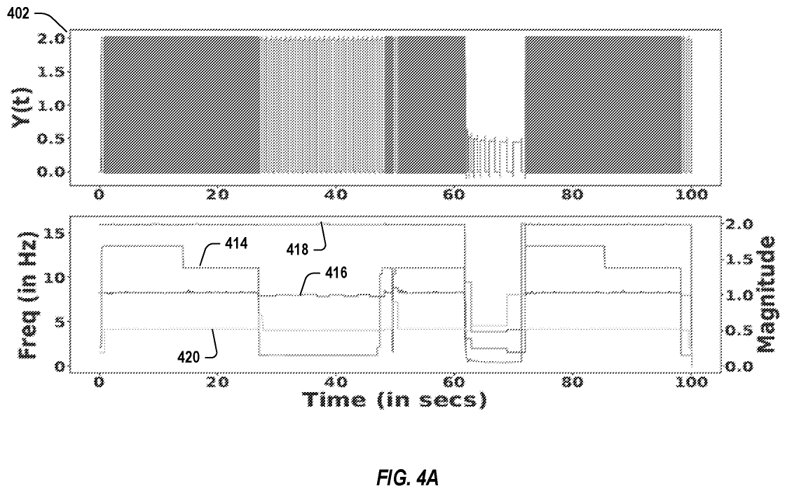

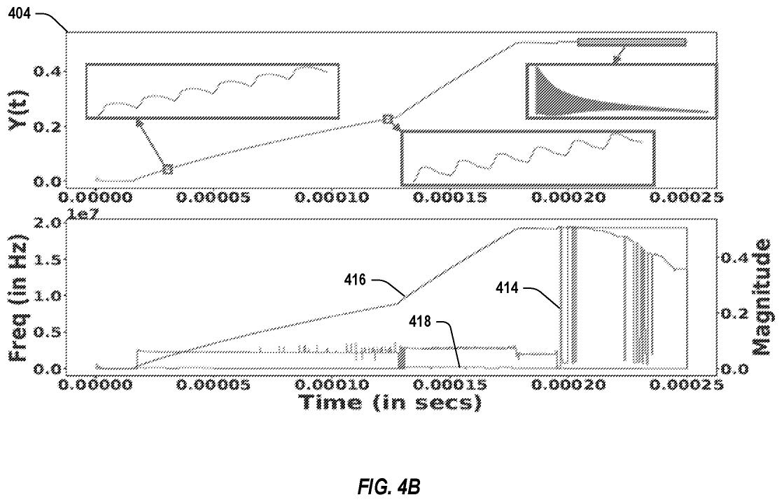

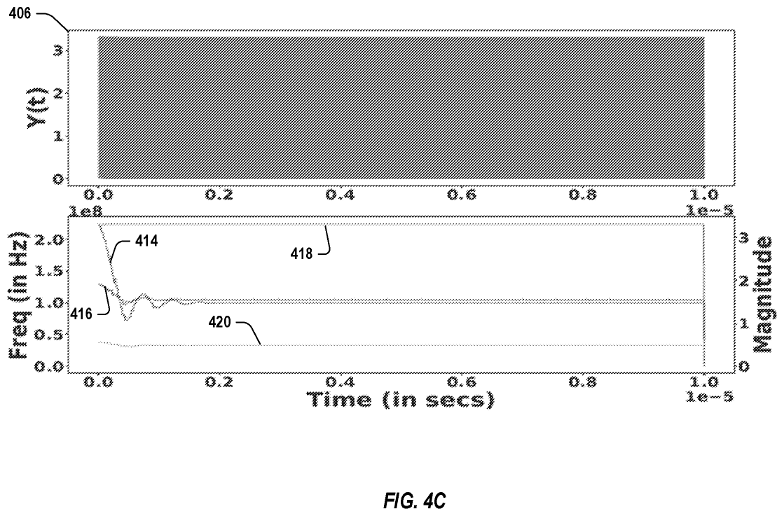

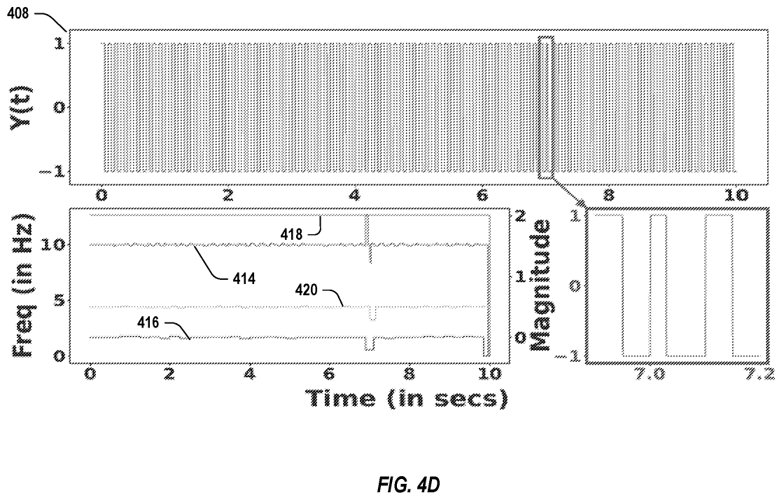

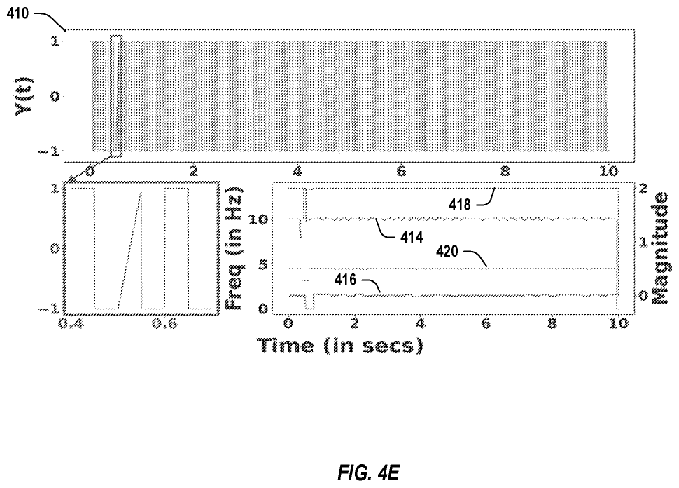

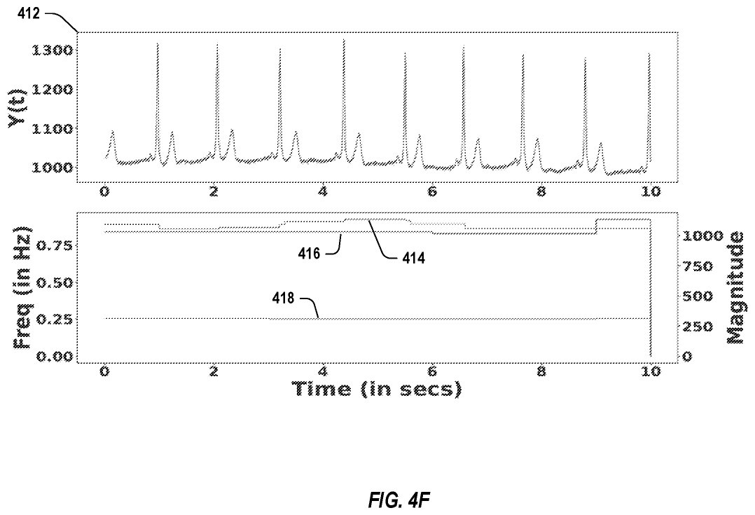

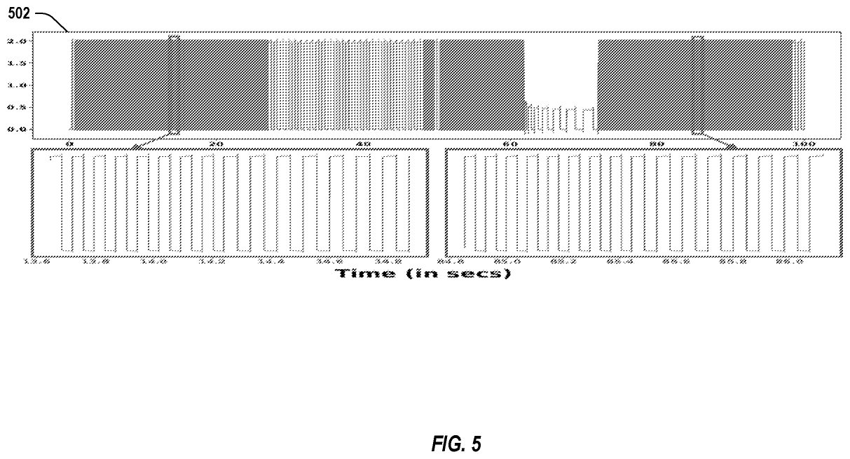

The first waveform under is category is from a digital controlled oscillator from Texas Instruments. Graph 402 in FIG. 4A shows the results on this waveform. In FIGS. 4A-4F, experimental results on waveforms are depicted from industrial and benchmark circuits. Frequency markings 414 are shown on the left axis while markings for DC-reference 416, peak-to-peak amplitude 418, and duty-cycle 420 are shown on right axis. The approach of computing frequency is unaffected by the ever-changing reference of the signal about which it oscillates. Apart from the obvious regions of frequency changes, one interesting point to note is that there are noticeable changes in the frequency variation that have been captured, which are not visible through the naked eye in the original wave. For example, an abrupt frequency change is noticed at time 14 s and 86 s in graph 402. Though it seems that there is no apparent change in frequency, a zoomed-in view (as shown in graph 502 in FIG. 5) shows that there is a change in the frequency. The circuit designer confirmed that this is due to the fact that at 14 s and 86 s frequency trim values are loaded from the programmed memory after the chip is powered up which adjusts the frequency. A power supply brownout (powerdown-powerup) cycle occurs at 60 s which not only changes the frequency of oscillation but also the DC Reference. There is also a single cycle fault occurring at 48 s which has been captured as a small sharp dip in frequency.

Graph 404 in FIG. 4B shows the result of applying the algorithms to the output of a buck regulator circuit. Computing the frequency of oscillation of the buck output is a non-trivial task due to the continuously changing reference of oscillation. The algorithm is able to perform the computation. It also captures the minute variations of frequency noticed around 0.1 ms.

Graph 406 in FIG. 4C shows the result on the output of a phase locked loop (PLL). The frequency variation shows the typical behavior of a second order control loop found inside the PLL. The frequency initially starts from an arbitrary value, and eventually reaches steady state value of 100 MHz.

The next test case is a clock signal of an industrial audio amplifier (Class-D). In the first scenario shown in graph 408 in FIG. 4D the signal exhibited a cycle with reduced duty cycle. Graph 410 in FIG. 4E shows the scenario where the signal gave a triangular pulse instead of a square one. Both these deviations, also correlating with a design issue or bug, were caught by the algorithm.

The algorithm was applied on another random waveform from the set of publicly available ECG waveforms. As plotted in graph 412 in FIG. 4F, these types of waveforms are periodic over comparatively long periods of time, with sharp spikes appearing at regular intervals. Since the widths of the pulses are much smaller compared to one time period, their DC references are almost equal to their base levels. Similarly, the peak-to-peak amplitude is expected to be dominated by the sharp swing of the spikes.

In this work, proposed are novel techniques to track various artifacts of a periodic signal by abstracting the signal as a sequence of literals. The crucial differentiating factor of the approach from the existing ones is that the computation is performed in absence of any knowledge regarding the supplied signal. This makes the method more generic and widely applicable in an unknown verification setup. Moreover, exploration of such periodic artifacts also leads to comprehensive verification closure for AMS designs. Experiments over industrial and other benchmarks successfully demonstrate the applicability of the proposed approach.

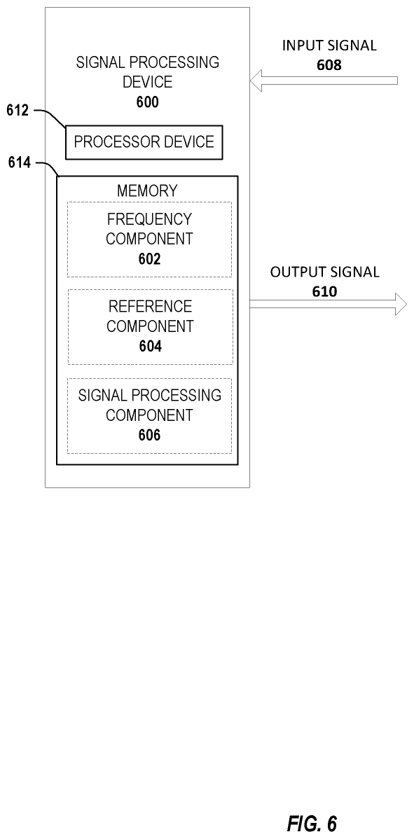

FIG. 6 illustrates a signal processing device 600 that can determine parameters of a periodic coverage artifact in a signal according to one or more aspects of the present disclosure.

The signal processing device 600 can include a processor device 612 and a memory 614. The memory 614 can store computer executable instructions or components that can be executed by the processor 612 to perform various operations. For example, the frequency component 602 can sample the signal 608 to abstract it as an ordered set of a sequence of literals that correspond to a time stamps in a first time period. Then, the frequency component 602 can iteratively determine whether a sub-sequence of literals repeats in a first window of time within the first time period, wherein after every iteration, the first window of time is lengthened. Subsequently, the frequency component 602 can determine a frequency of the periodic coverage artifact based on a length of time between repeating sub-sequences of literals.

The reference component 604 can then uniformly resample the signal in a second window of time to determine a temporary reference voltage that is a mean of all samples in the second window of time. The reference component 604 can then determine a list of reference values for a set of time periods, wherein a reference value of the list of reference values is a mean of each sample in a respective time period, wherein each time period of the set of time periods is defined by consecutive positive (or negative) level crossings of the temporary reference voltage. Subsequently, the reference component 604 can then determine a DC reference based on a median of the list of reference values.

After the frequency and/or DC reference has been identified or determined, the signal processing device 600 can perform one or more signal processing operations via the signal processing component 606 on the incoming signal 608 to generate an outgoing signal 610.

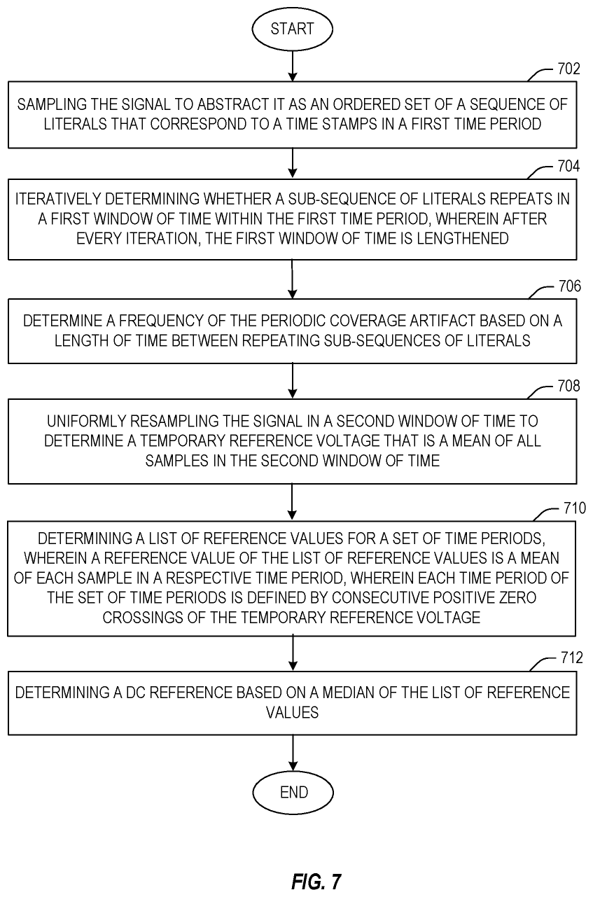

Turning now to FIG. 7, illustrated is a flowchart of a method for determining parameters of a periodic coverage artifact in a signal.

At step 702, the method includes sampling the signal to abstract it as an ordered set of a sequence of literals that correspond to a time stamps in a first time period.

At step 704, the method includes iteratively determining whether a sub-sequence of literals repeats in a first window of time within the first time period, wherein after every iteration, the first window of time is lengthened. In an embodiment, this can further include mitigating signal noise when determining whether the sub-sequence of literals repeats by employing a tolerance parameter that defines a maximum number of literals that are ignored when determining whether the sub-sequence of literals repeats.

In another embodiment, a number of literals in the repeating sub-sequences of literals is an even number, and wherein for each literal in the repeating sub-sequences of literals, a preceding literal and a succeeding literal are immediate neighbors of the literal.

In another embodiment, after identifying the repeating sub-sequence of literals, the method can include shifting the first window of time to a second time period.

At step 706, the method includes determining a frequency of the periodic coverage artifact based on a length of time between repeating sub-sequences of literals.

At step 708, the method includes uniformly resampling the signal in a second window of time to determine a temporary reference voltage that is a mean of all samples in the second window of time.

At step 710, the method includes determining a list of reference values for a set of time periods, wherein a reference value of the list of reference values is a mean of each sample in a respective time period, wherein each time period of the set of time periods is defined by consecutive positive (or negative) level crossings of the temporary reference voltage.

At step 712, the method includes determining a DC reference based on a median of the list of reference values.

In various other embodiments, the method can also include performing a signal processing operation based on the frequency and the DC reference.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A method to determine parameters of a periodic coverage artifact in a signal, comprising:
sampling the signal to abstract it as an ordered set of a sequence of literals that correspond to a sequence of time stamps in a first time period;
iteratively determining whether a sub-sequence of literals repeats in a first window of time within the first time period, wherein after every iteration, the first window of time is lengthened;
determining a frequency of the periodic coverage artifact based on a length of time between repeating sub-sequences of literals;
uniformly resampling the signal in a second window of time to determine a temporary reference voltage that is a mean of all samples in the second window of time;
determining a list of reference values for a set of time periods, wherein a reference value of the list of reference values is a mean of each sample in a respective time period, wherein each time period of the set of time periods is defined by consecutive positive level crossings of the temporary reference voltage; and
determining a Direct Current (DC) reference based on a median of the list of reference values.

2. The method of claim 1, further comprising:
performing a signal processing operation based on determining the frequency and the DC reference.

3. The method of claim 1, further comprising:
mitigating signal noise when determining whether the sub-sequence of literals repeats by employing a tolerance parameter that defines a maximum number of literals that are ignored when determining whether the sub-sequence of literals repeats.

4. The method of claim 1, wherein a number of literals in the repeating sub-sequences of literals is an even number.

5. The method of claim 1, wherein for each literal in the repeating sub-sequences of literals, a preceding literal and a succeeding literal are immediate neighbors of the literal.

6. The method of claim 1, further comprising:
in response to identifying the repeating sub-sequence of literals, shifting the first window of time to a second time period.

7. The method of claim 6, wherein there are respective DC references and frequencies of periodic coverage artifacts for each of the first time period and the second time period.

8. The method of claim 1, further comprising:
generating a list of starting timestamps and a list of ending timestamps corresponding to respective starting points and ending points of each occurrence of the repeating sub-sequences of literals.

9. The method of claim 1, wherein the second window of time comprises at least two occurrences of the repeating sub-sequences of literals.

10. The method of claim 1, further comprising:
determining a peak to peak value of a time period based on a difference between a maximum value and a minimum value in the time period.

11. The method of claim 1, further comprising:
determining a duty cycle based on a first time interval between a positive level crossing and a negative level crossing divided by a time period associated with the first time interval.

12. A signal processing device, comprising:
a memory that stores computer-executable instructions;
a processor that executes the computer-executable instructions to perform operations, comprising:
sampling a signal to abstract it as an ordered set of a sequence of literals that correspond to a time stamps in a first time period;
iteratively determining whether a sub-sequence of literals repeats in a first window of time within the first time period, wherein after every iteration, the first window of time is lengthened;
determine a frequency of a periodic coverage artifact of the signal based on a length of time between repeating sub-sequences of literals;
uniformly resampling the signal in a second window of time to determine a temporary reference voltage that is a mean of all samples in the second window of time;
determining a list of reference values for a set of time periods, wherein a reference value of the list of reference values is a mean of each sample in a respective time period, wherein each time period of the set of time periods is defined by consecutive positive level crossings of the temporary reference voltage; and
determining a Direct Current (DC) reference based on a median of the list of reference values.

13. The signal processing device of claim 12, wherein the operations further comprise:
performing a signal processing operation based on determining the frequency and the DC reference.

14. The signal processing device of claim 12, wherein the operations further comprise:
mitigating signal noise when determining whether the sub-sequence of literals repeats by employing a tolerance parameter that defines a maximum number of literals that are ignored when determining whether the sub-sequence of literals repeats.

15. The signal processing device of claim 12, wherein a number of literals in the repeating sub-sequences of literals is an even number.

16. The signal processing device of claim 12, wherein for each literal in the repeating sub-sequences of literals, a preceding literal and a succeeding literal are immediate neighbors of the literal.

17. The signal processing device of claim 12, wherein the operations further comprise:
in response to identifying the repeating sub-sequence of literals, shifting the first window of time to a second time period.

18. The signal processing device of claim 17, wherein there are respective DC references and frequencies of periodic coverage artifacts for each of the first time period and the second time period.

19. The signal processing device of claim 12, wherein the operations further comprise:
generating a list of starting timestamps and a list of ending timestamps corresponding to respective starting points and ending points of each occurrence of the repeating sub-sequences of literals.

20. The signal processing device of claim 12, wherein the second window of time comprises at least two occurrences of the repeating sub-sequences of literals.

21. The signal processing device of claim 12, wherein the operations further comprise:
determining a peak to peak value of a time period based on a difference between a maximum value and a minimum value in the time period.

22. The signal processing device of claim 12, wherein the operations further comprise:
determining a duty cycle based on a first time interval between a positive level crossing and a negative level crossing divided by a time period associated with the first time interval.

23. A non-transitory computer-readable medium comprising computer executable instructions, that when executed by a processor, perform operations, comprising:
sampling a signal to abstract it as an ordered set of a sequence of literals that correspond to a time stamps in a first time period;
iteratively determining whether a sub-sequence of literals repeats in a first window of time within the first time period, wherein after every iteration, the first window of time is lengthened;
determine a frequency of a periodic coverage artifact of the signal based on a length of time between repeating sub-sequences of literals;
uniformly resampling the signal in a second window of time to determine a temporary reference voltage that is a mean of all samples in the second window of time;
determining a list of reference values for a set of time periods, wherein a reference value of the list of reference values is a mean of each sample in a respective time period, wherein each time period of the set of time periods is defined by consecutive positive level crossings of the temporary reference voltage; and
determining a Direct Current (DC) reference based on a median of the list of reference values.

24. The non-transitory computer readable medium of claim 23, wherein the operations further comprise:
performing a signal processing operation based on determining the frequency and the DC reference.
